(19) United States
(12) Patent Application Publication
(10) Pub. No.: US 2017/0144920 A1
(43) Pub. Date: May 25, 2017

(54) CRYSTALLINE OXIDES, PREPARATION THEREOF AND CONDUCTIVE PASTES CONTAINING THE SAME

(71) Applicant: GIGA SOLAR MATERIALS CORP., HSINCHU (TW)

(72) Inventors: CHIH-HSIEN YEH, HSINCHU (TW); PO-YANG SHIH, HSINCHU (TW); CHIH-JEN SHEN, HSINCHU (TW); PENG-SHENG TSENG, HSINCHU (TW); PI-YU HSIN, HSINCHU (TW); TSUNG YING TSAI, HSINCHU (TW)

(73) Assignee: GIGA SOLAR MATERIALS CORP., HSINCHU (TW)

(21) Appl. No.: 15/341,751

(22) Filed: Nov. 2, 2016

Related U.S. Application Data
(60) Provisional application No. 62/258,266, filed on Nov. 20, 2015.

(51) Int. Cl. C03C 8/18; C03C 8/10; H01L 31/0224; C03C 4/14; C09D 5/24; H01L 31/0216; C03C 3/12; C03C 8/16

(52) U.S. Cl. CPC C03C 8/18; C03C 3/122; C03C 8/10; C03C 8/16; C03C 4/14; C09D 5/24; H01L 31/02168; H01L 31/022441; C03C 2204/00; C03C 2205/00

(57) ABSTRACT

The present invention provides a novel crystalline oxide, a process for producing the crystalline oxides, a conductive paste comprising the crystalline oxides and an article comprising a substrate and an abovementioned conductive paste applied on the substrate.

### CROSS-REFERENCE TO RELATED APPLICATIONS

The present application claims priority to U.S. Provisional Patent Application No. 62/258,266, filed on Nov. 20, 2015 entitled CRYSTALLINE OXIDES, PREPARATION THEREOF AND CONDUCTIVE PASTES CONTAINING THE SAME, the contents of which are incorporated by reference.

### BACKGROUND OF THE INVENTION

Field of the Invention

The present invention relates a novel crystalline oxide, a process for producing the crystalline oxides, a conductive paste comprising the crystalline oxides and an article comprising a substrate and an abovementioned conductive paste applied on the substrate.

Description of Related Art

Conductive pastes for solar cells typically comprise a conductive metal or the derivative thereof (such as silver particles), a glass frit (such as lead oxide-containing glass) and an organic vehicle. Conventional glass frits used in conductive pastes are amorphous.

### BRIEF SUMMARY OF THE INVENTION

It is an unexpected discovery that crystalline oxides, particularly Pb—Te—Bi-oxides are suitable for use in a conductive paste and the solar cells comprising an electrode formed from the conductive pastes containing said crystalline oxides may exhibit a superior solar photovoltaic conversion efficiency to the solar cells comprising an electrode formed from the conductive paste containing a conventional glass frit and a comparable pulling force, thereby providing comparable adhesion to the substrate for solar cells.

Accordingly, the first aspect of the present invention is to provide a novel crystalline oxide, particularly crystalline Pb—Te—Bi-oxides. The second aspect of the present invention is to provide a process for producing the crystalline oxides, particularly crystalline Pb—Te—Bi-oxides. The third aspect of the present invention is to provide a conductive paste comprising the crystalline oxides, particularly crystalline Pb—Te—Bi-oxides. The fourth aspect of the present invention is to provide an article comprising a substrate and an abovementioned conductive paste applied on the substrate. Particularly, the article is a solar cell.

### BRIEF DESCRIPTIONS OF DRAWINGS

FIG. 1 shows the DSC analysis result of the PbO—TeO₂—Bi₂O₃-based glass employed in Examples.

FIG. 2 shows the XRD analysis result of the crystalline Pb—Te—Bi-oxides of the present invention prepared in Examples.

### DETAILED DESCRIPTION OF THE INVENTION

The crystalline Pb—Te—Bi-oxide of the present invention can be represented by the formula BiₐPb_{b}Te_{c}O_{d}, wherein the stoichiometric a=0-32, b=0-6, c=1-4 and d=0.6-50. The above crystalline oxides contain a cubic (C), tetragonal (T), monoclinic (M) or orthorhombic (O) crystalline structure, such as Pb₂TeO₅(M), Pb₂Te₃O₈ (O), PbTeO₃ (T), PbTeO₃ (M), Pb₃TeO₆ (M), Pb₅TeO₇, Pb₄Te_{1.5}O₇ (O), Pb₃TeO₅, Pb₂TeO₄ (M), Pb₂Te₃O₈ (O), Pb₂Te₃O₇ (C), Pb₃TeO₅ (C), PbTeO₃ (C), PbTeO₄ (T), PbTe₃O₇ (C), PbTeO₃ (O), PbBi₆TeO₁₂, (Bi₁₂Te₄O₁₁)_{0.6} (C), Bi₂Te₂O₇ (O), Bi₂Te₂O₈ (M), Bi₂Te₄O₁₁ (M), Bi₂TeO₅ (O), Bi₂TeO₆ (O), Bi₂Te₄O₁₁ (C), Bi₆Te₂O₁₃ (O), BiTe₃O_{7.5} (C), Bi₂Te₂O₇, Bi₆Te₂O₁₅ (O), Bi₃₂TeO₅₀ (T), Bi₄TeO₈ (C), Bi₁₆Te₅O₃₄ (T), etc. Among the crystalline oxides, PbTeO₃ (T), PbTeO₃ (M), PbTeO₃ (C), Pb₂Te₃O₇ (C), PbTe₃O₇ (C), PbBi₆TeO₁₂, (Bi₂Te₄O₁₁)_{0.6} (C), Bi₂TeO₅ (O), Bi₂Te₂O₇ (O) and BiTe₃O_{7.5} (C) are preferred. In one embodiment, the crystalline BiₐPb_{b}Te_{c}O_{d} is predominantly present in the crystalline state of Pb_{b}Te_{c}O_{d} in which b=1-3, c=1-3 and d=3-8. In another embodiment, the crystalline BiₐPb_{b}Te_{c}O_{d} is predominantly present in the crystalline state of BiₐTe_{c}O_{d} in which a=1-4, c=1-3 and d=0.6-11. In a further embodiment, the crystalline BiₐPb_{b}Te_{c}O_{d} is predominantly present in the crystalline state of PbTeBi₆O₁₂.

The crystalline Pb—Te—Bi-oxide is a powder in at least one shape selected from sphere, flake, granular-shape, sheet-shape, dendritic-shape and/or spherical-shape.

In one embodiment, the crystalline Pb—Te—Bi-oxide of the present invention has an average particle size D₅₀ of 0.1-15 μm.

The crystalline Pb—Te—Bi-oxide of the present invention may further comprise one or more elements selected from the group consisting of silicon (Si), boron (B), phosphorus (P), barium (Ba), sodium (Na), magnesium (Mg), zinc (Zn), calcium (Ca), strontium (Sr), tungsten (W), aluminum (Al), lithium (Li), potassium (K), zirconium (Zr), vanadium (V), selenium (Se), iron (Fe), indium (In), molybdenum (Mo), manganese (Mn), tin (Sn), nickel (Ni), antimony (Sb), silver (Ag), erbium (Er), germanium (Ge), titanium (Ti), gallium (Ga), cerium (Ce), niobium (Nb), samarium (Sm) and lanthanum (La) or the oxide thereof.

In one embodiment, the crystalline Pb—Te—Bi-oxide of the present invention is preferably prepared from a PbO—TeO₂—Bi₂O₃-based glass. The PbO—TeO₂—Bi₂O₃-based glass is defined to refer to a glass comprising about 5-70 mole % of tellurium oxide, about 10-60 mole % of lead oxide and about 0.1-30 mole % of bismuth oxide. Preferably, PbO—TeO₂—Bi₂O₃-based glass is defined to refer to a glass comprising about 5-70 mole % of TeO₂, about 10-60 mole % of PbO and about 0.1-30 mole % of Bi₂O₃. The PbO—TeO₂—Bi₂O₃-based glass may further comprise one or more elements or the oxide thereof mentioned above in an amount of about 0.1 mole % to about 20 mole % of the PbO—TeO₂—Bi₂O₃-based glass.

Another aspect of the present invention is to provide a process for preparing crystalline oxides, particularly crystalline Pb—Te—Bi-oxides. In one embodiment, the present invention provides a process for preparing crystalline Pb—Te—Bi-oxides comprising the steps of: (i) providing a PbO—TeO₂—Bi₂O₃-based glass and (ii) treating said glass at a crystallization temperature for about 3 to about 24 hours. The PbO—TeO₂—Bi₂O₃-based glass employed in step (i) may be in the form of powders, bulks or frits, preferably glass powders. In accordance with the present invention, the crystalline temperature for heat treatment of the PbO—TeO₂—Bi₂O₃-based glass in step (ii) must be higher than the Tg (glass transition temperature) of the PbO—TeO₂—Bi₂O₃-based glass. In one embodiment, the heat treatment of the PbO—TeO₂—Bi₂O₃-based glass in step (ii) is carried out at a crystallization temperature of about 320° C. to about 400° C. In another embodiment, the heat treatment of the PbO—TeO₂—Bi₂O₃-based glass in step (ii) is carried out at a crystallization temperature of about 320° C. In a further embodiment, the heat treatment of the PbO—TeO₂—Bi₂O₃-based glass in step (ii) is carried out at a crystallization temperature of about 400° C.

In another embodiment, the present invention provides a process for preparing crystalline Pb—Te—Bi-oxides by solid state reaction comprising reacting stoichiometric ratios of the oxides, such as PbO, Pb₃O₄, TeO₂, Bi₂O₃, etc., as the raw materials at a temperature of about 200° C. to about 900° C. for about 0.5 to about 12 hours. Preferably, the solid state reaction is carried out at a temperature of about 400° C. Additional oxides such as Li₂O, Li₂CO₃, etc. may be added in the solid state reaction, depending on the type of crystalline oxides to be produced. In one embodiment, crystalline PbTeO₃ is produced by reacting PbO and TeO₂ in an about 1:1 molar ratio at a temperature of 400° C. for about 0.5 to about 12 hours. Journal of Materials Science 23 (1988) 1871-1876 in its entirety is incorporated herein by reference

In a further embodiment, the present invention provides a process for preparing crystalline oxides by controlling the cooling rate of a high temperature fluid materials during the manufacture process to crystallize the fluid materials. Preferably, said fluid materials are selected from one or more amorphous glasses being heated to high temperature. In particular, the present invention provides a process for preparing crystalline Pb—Te—Bi-oxides comprising controlling the cooling rate of the high temperature fluid materials during the manufacture of a PbO—TeO₂—Bi₂O₃-based glass to enable crystallization of the fluid materials in a slowly cooling manner. Arun K. Varshneya, Fundamentals of Inorganic Glasses, Chapter 2 (pages 13-17) in its entirety is incorporated herein by reference. The crystalline oxides produced by this process may simultaneously contain glass states and crystalline states.

A further aspect of the present invention is to provide a conductive paste comprising (a) a conductive metal or the derivative thereof, (b) crystalline oxides, in particular crystalline Pb—Te—Bi-oxides and (c) an organic vehicle.

The conductive metal of the present invention is not subject to any special limitation as long as it does not have an adverse effect on the technical effect of the present invention. The conductive metal can be one single element selected from the group consisting of silver, aluminum and copper; and also can be alloys or mixtures of metals, such as gold, platinum, palladium, nickel and the like. From the viewpoint of conductivity, pure silver is preferable.

In the case of using silver as the conductive metal, it can be in the form of silver metal, silver derivatives and/or the mixture thereof. Examples of silver derivatives include silver oxide (Ag₂O), silver salts (such as silver chloride (AgCl), silver nitrate (AgNO₃), silver acetate (AgOOCCH₃), silver trifluoroacetate (AgOOCCF₃) or silver phosphate (Ag₃PO₄), silver-coated composites having a silver layer coated on the surface or silver-based alloys or the like.

The conductive metal can be in the form of powder (for example, spherical shape, flakes, irregular form and/or the mixture thereof) or colloidal suspension or the like.

The average particle size of the conductive metal is not subject to any particular limitation, while 0.1 to μm is preferable. Mixtures of conductive metals having different average particle sizes, particle size distributions or shapes, and etc. can also be employed.

In one preferred embodiment of the present invention, the conductive metal or the derivative thereof comprises about 85% to about 99.5% by weight of the solid components of the conductive paste.

In addition to crystalline oxides, particularly crystalline Pb—Te—Bi-oxides as the component (b), (d) a Bi₂O₃—SiO₂-based glass frit may be optionally added in the conductive paste. The weight ratio of the crystalline Pb—Te—Bi-oxides to the Bi₂O₃—SiO₂-based glass in the conductive paste is preferably about 2.5:1 to about 8:1, particularly preferably about 8:1. The Bi₂O₃—SiO₂-based glass frit is defined to refer a glass frit comprising about 0.1-60 mole % of bismuth oxide and 10-60 mole % of silicon oxide. Preferably, Bi₂O₃—SiO₂-based glass is defined to refer to a glass frit comprising about 0.1-60 mole % of Bi₂O₃ and about 10-60 mole % of SiO₂. In accordance with the present invention, the Bi₂O₃—SiO₂-based glass frit may further optionally comprise one or more elements selected from the group consisting of silicon (Si), boron (B), phosphorus (P), barium (Ba), sodium (Na), magnesium (Mg), zinc (Zn), calcium (Ca), tellurium (Te), strontium (Sr), tungsten (W), aluminum (Al), lithium (Li), potassium (K), zirconium (Zr), lead (Pb), vanadium (V), selenium (Se), iron (Fe), indium (In), manganese (Mn), tin (Sn), nickel (Ni), antimony (Sb), silver (Ag), molybdenum (Mo), erbium (Er), germanium (Ge), titanium (Ti), gallium (Ga), cerium (Ce), niobium (Nb), samarium (Sm) and lanthanum (La) or the oxide thereof in the in an amount of about 0.1 mole % to about 30 mole % of the Bi₂O₃—SiO₂-based glass frit. The glass frit has an average particle size D₅₀ of about 0.1-10 μm.

The crystalline Pb—Te—Bi-oxides as the component (b) may also be used in combination with the component (e) a TeO₂—Bi₂O₃-based glass frit for preparation of the conductive paste. The weight ratio of the crystalline Pb—Te—Bi-oxides to the TeO₂—Bi₂O₃-based glass in the conductive paste is preferably about 2.5:1 to about 8:1, particularly preferably about 8:1.

The crystalline Pb—Te—Bi-oxides as the component (b) may also be used in combination with the component (f) a SiO₂—TeO₂—PbO-based glass frit for preparation of the conductive paste. The weight ratio of the crystalline Pb—Te—Bi-oxides to the SiO₂—TeO₂—PbO-based glass in the conductive paste is preferably about 2.5:1 to about 8:1, particularly preferably about 8:1.

The crystalline Pb—Te—Bi-oxides as the component (b) may also be used in combination with the component (g) a TeO₂—PbO—Bi₂O₃—SeO₂-based glass frit for preparation of the conductive paste. The weight ratio of the crystalline Pb—Te—Bi-oxides to the TeO₂—PbO—Bi₂O₃—SeO₂-based glass in the conductive paste is preferably about 2.5:1 to about 8:1, particularly preferably about 8:1.

The crystalline Pb—Te—Bi-oxides as the component (b) may also be used in combination with the component (h) a Bi₂O₃—SiO₂—WO₃-based glass frit for preparation of the conductive paste. The weight ratio of the crystalline Pb—Te—Bi-oxides to the Bi₂O₃—SiO₂—WO₃-based glass in the conductive paste is preferably about 2.5:1 to about 8:1, particularly preferably about 8:1.

In the present invention, the inorganic components comprising the solids of (a) the conductive metal or derivatives thereof and (b) the crystalline oxides are mixed with the organic vehicle (c) to form a conductive paste, wherein the organic vehicle (c) could be in liquid form. Suitable organic vehicles can allow said inorganic components to be uniformly dispersed therein and have a proper viscosity to deliver said inorganic components to the surface of the antireflective coating by screen printing, stencil printing or the like. The conductive paste also must have good drying rate and excellent fire-through properties.

The organic vehicle is a solvent which is not subject to particular limitation and can be properly selected from conventional solvents for conductive pastes. Examples of solvents include alcohols (e.g., isopropyl alcohol), esters (e.g., propionate, dibutyl phthalate) and ethers (e.g., butyl carbitol) or the like or the mixture thereof. Preferably, the solvent is an ether having a boiling point of about 120° C. to about 300° C. Most preferably, the solvent is butyl carbitol. The organic vehicle can further comprise volatile liquids to promote the rapid hardening after application of the conductive paste onto the semiconductor substrate.

In one preferred example of the present invention, the organic vehicle is a solution comprising a polymer and a solvent. Because the organic vehicle composed of a solvent and a dissolved polymer disperses the inorganic components comprising a conductive metal and a glass frit, a conductive paste having suitable viscosity can be easily prepared. After printing on the surface of the antireflective coating and drying, the polymer increases the adhesiveness and original strength of the conductive paste.

Examples of polymers include cellulose (e.g., ethyl cellulose), nitrocellulose, ethyl hydroxyethylcellulose, carboxymethylcellulose, hydroxypropylcellulose or other cellulose derivatives), poly(meth)acrylate resins of lower alcohols, phenolic resins (e.g., phenol resin), alkyd resins (e.g., ethylene glycol monoacetate) or the like or the mixtures thereof. Preferably, the polymer is cellulose. Most preferably, the polymer is ethyl cellulose.

In one preferred example of the present invention, the organic vehicle comprises ethyl cellulose dissolved in ethylene glycol butyl ether.

In another preferred example of the present invention, the organic vehicle comprises one or more functional additives. Examples of functional additives include viscosity modifiers, dispersing agents, thixotropic agents, wetting agents and/or optionally other conventional additives (for example, colorants, preservatives or oxidants), and etc. Functional additives are not subject to particular limitation as long as they do not adversely affect the technical effect of the present invention.

In another embodiment of the present invention, the organic vehicle comprises one or more functional additives, such as viscosity modifiers, dispersing agents, thixotropic agents, wetting agents, etc.

Another aspect of the present invention is to provide an article comprising a semiconductor substrate and an abovementioned conductive paste applied on the semiconductor substrate. In one embodiment of the present invention, the article is a semiconductor device. In another embodiment of the present invention, the semiconductor device is a solar cell.

The conductive paste of the present invention is first printed on the antireflective coating as grid lines or other patterns wherein the printing step could be carried out by conventional methods, such as screen printing or stencil printing, etc. Then, the fire-through step is carried out at a oxygen-containing atmosphere (such as ambient air) by heating to a set point (peak firing temperature) of about 900° C. to about 950° C., preferably about 910° C. to about 920° C. for about 0.05 to about 5 minutes to remove the organic vehicle and fire the conductive metal, whereby the conductive paste after-firing is substantially free of any organic substances and the conductive paste after-firing penetrates through the antireflective coating to form ohmic contact with the semiconductor substrate and one or more antireflective coating(s) beneath. This fire-though step forms the electrical contact between the semiconductor substrate and the grid lines (or in other patterns) through metal contacts and therefore front electrodes are formed.

In one preferred example of the present invention, the semiconductor substrate comprises amorphous, polymorphous or monocrystalline silicon. In another preferred example of the present invention, the antireflective coating comprises silicon dioxide, titanium dioxide, silicon nitride or other conventional coatings.

The foregoing has outlined the technical features and the technical effects of the present invention. It should be appreciated by a person of ordinary skill in the art that the specific embodiments disclosed may be easily combined, modified, replaced and/or conversed for other articles, processes or usages within the spirit of the present invention. Such equivalent scope does not depart from the protection scope of the present invention as set forth in the appended claims.

Without intending to limit the present invention, the present invention is illustrated by means of the following examples.

### Examples

### Preparation of Crystalline Pb—Te—Bi-Oxides

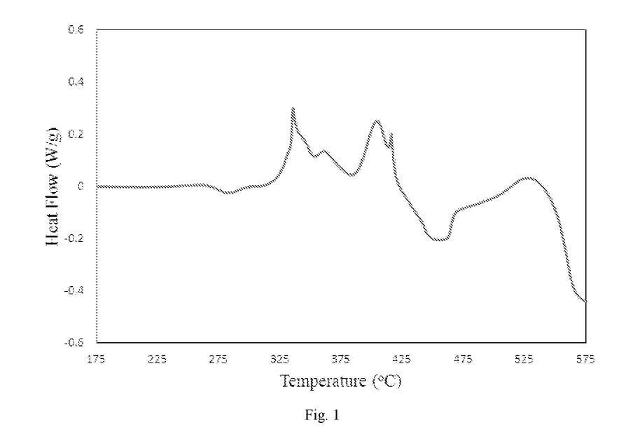

The crystallization temperature of a PbO—TeO₂—BiO₂-based glass was first examined by Differential Scanning calorimetry (DSC). To measure the crystallization temperature, 20 mg of the PbO—TeO₂—BiO₂-based glass powder was heated from the room temperature to 600° C. at a speed of 20° C./min and then cooled down with the use of N₂ as the carrier gas. The DSC analysis result is shown in FIG. 1.

From the DSC analysis result, it indicates that the PbO—TeO₂—BiO₂-based glass has a glass transition temperature of about 266° C. and at least two crystallization phases with two peaks of crystallization temperatures (i.e., about 320° C. and 400° C.) are present.

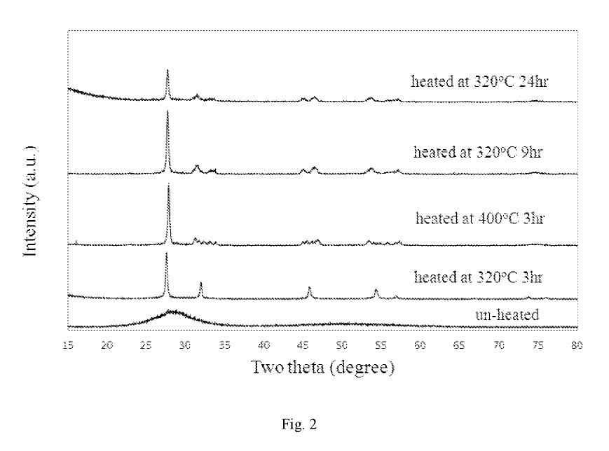

Then, the PbO—TeO₂—BiO₂-based glass powder was subjected to heat treatment at about 320° C. and about 400° C. for 3 hours to 24 hours, respectively. After heat treatment, XRD analysis was carried out for a sample of the glass and the result shows that substantially full crystallization of the glass occurred and no substantial amount of the amorphous state was present. The XRD analysis result is shown in FIG. 2.

### Preparation of Conductive Pastes Containing Crystalline Pb—Te—Bi-Oxides

An organic vehicle for conductive pastes was prepared by dissolving 5 to 25 grams of ethyl cellulose in 5 to 75 grams of ethylene glycol butyl ether and adding a small amount of a viscosity modifier, a dispersing agent, a thixotropic agent, a wetting agent therein. Then, a conductive paste was prepared by mixing and dispersing 80 to 99.5 grams of industrial grade silver powder, 0.1 to 5 grams of a crystalline Pb—Te—Bi-oxides prepared by the above process (hereinafter referred to as “C-320” for the crystalline Pb—Te—Bi-oxides obtained by heat treatment at 320° C., and “C-400” for the crystalline Pb—Te—Bi-oxides obtained by heat treatment at 400° C.), 0.1 to 5 grams of a Bi₂O₃—SiO₂-based glass frit (hereinafter referred to as “G2”) and 10 to 30 grams of an organic vehicle in a three-roll mill. A conductive paste comprising untreated PbO—TeO₂—Bi₂O₃ glass frit (hereinafter referred to as “G1”) as the control was prepared in a similar manner.

In one embodiment, 0.1 to 5 grams of a TeO₂—Bi₂O₃-based glass frit (hereinafter referred to as “G3”) could be used in combination with the present invention for preparation of conductive pastes containing crystalline Pb—Te—Bi-Oxides. In one embodiment, G3 is substantially free of lead. Specifically, G3 does not contain any intentionally-added lead component. More specifically, G3 contains a lead component in an amount of less than 1000 ppm.

In one embodiment, 0.1 to 5 grams of a SiO₂—TeO₂—PbO-based glass frit (hereinafter referred to as “G4”) could be used in the present invention for preparation of conductive pastes containing crystalline Pb—Te—Bi-Oxides.

In one embodiment, 0.1 to 5 grams of a TeO₂—PbO—Bi₂O₃—SeO₂-based glass frit (hereinafter referred to as “G5”) could be used in the present invention for preparation of conductive pastes containing crystalline Pb—Te—Bi-Oxides.

In one embodiment, 0.1 to 5 grams of a Bi₂O₃—SiO₂-based glass frit further comprising WO₃ as a Bi₂O₃—SiO₂—WO₃-based glass frit (hereinafter referred to as “G6”) could be used in the present invention for preparation of conductive pastes containing crystalline Pb—Te—Bi-Oxides. In one embodiment, G6 is substantially free of lead. Specifically, G6 does not contain any intentionally-added lead component. More specifically, G6 contains a lead component in an amount of less than 1000 ppm.

In one embodiment, G3 glass frit comprises 55 wt %˜80 wt % TeO₂, preferably 60 wt %˜70 wt % TeO₂.

In one embodiment, G3 glass frit comprises 5 wt %˜25 wt % Bi₂O₃, preferably 10 wt %˜20 wt % Bi₂O₃.

In one embodiment, G3 glass frit further comprises ZnO as a TeO₂—Bi₂O₃—ZnO-based glass frit with 0.1 wt %˜20 wt % ZnO, preferably 5 wt %˜15 wt % ZnO.

In one embodiment, G3 glass frit further comprises Li₂O as a TeO₂—Bi₂O₃—Li₂O-based glass frit with 0.1 wt %˜10 wt % Li₂O, preferably 1 wt %˜5 wt % Li₂O.

In one embodiment, G3 glass frit further comprises WO₃ as a TeO₂—Bi₂O₃—WO₃-based glass frit with 0.1 wt %˜10 wt % WO₃, preferably 1 wt %˜5 wt % WO₃.

In one embodiment, G3 glass frit further comprises B₂O₃ as a TeO₂—Bi₂O₃—B₂O₃-based glass frit with 0.1 wt %˜5 wt % B₂O₃, preferably 0.1 wt %˜3 wt % B₂O₃.

In one embodiment, G3 glass frit further comprises Al₂O₃ as a TeO₂—Bi₂O₃—Al₂O₃-based glass frit with 0.1 wt %˜5 wt % Al₂O₃, preferably 0.1 wt %˜3 wt % Al₂O₃.

In one embodiment, G3 glass frit further comprises MgO as a TeO₂—Bi₂O₃—MgO-based glass frit with 0.1 wt %˜5 wt % MgO, preferably 3 wt %˜5 wt % MgO.

In one embodiment, G4 glass frit comprises 20 wt %˜40 wt % SiO₂, preferably 25 wt %˜35 wt % SiO₂.

In one embodiment, G4 glass frit comprises 10 wt %˜35 wt % TeO₂, preferably 15 wt %˜30 wt % TeO₂.

In one embodiment, G4 glass frit comprises 10 wt %˜35 wt % PbO, preferably wt %˜30 wt % PbO.

In one embodiment, G4 glass frit further comprises ZnO as a SiO₂—TeO₂—PbO—ZnO-based glass frit with 0.1 wt %˜20 wt % ZnO, preferably 5 wt %˜15 wt % ZnO.

In one embodiment, G4 glass frit further comprises Bi₂O₃ as a SiO₂—TeO₂—PbO—Bi₂O₃-based glass frit with 1 wt %˜10 wt % Bi₂O₃, preferably 5 wt %˜10 wt % Bi₂O₃.

In one embodiment, G4 glass frit further comprises Sb₂O₃ as a SiO₂—TeO₂—PbO—Sb₂O₃-based glass frit with 1 wt %˜10 wt % Sb₂O₃, preferably 5 wt %˜10 wt % Sb₂O₃.

In one embodiment, G4 glass frit further comprises Li₂O as a SiO₂—TeO₂—PbO—Li₂O-based glass frit with 0.1 wt %˜10 wt % Li₂O, preferably 1 wt %˜5 wt % Li₂O.

In one embodiment, G4 glass frit further comprises B₂O₃ as a SiO₂—TeO₂—PbO—B₂O₃-based glass frit with 0.1 wt %˜10 wt % B₂O₃, preferably 5 wt %˜10 wt % B₂O₃.

In one embodiment, G4 glass frit further comprises Na₂O as a SiO₂—TeO₂—PbO—Na₂O-based glass frit with 0.1 wt %˜10 wt % Na₂O, preferably 1 wt %˜5 wt % Na₂O.

In one embodiment, G4 glass frit further comprises Al₂O₃ as a SiO₂—TeO₂—PbO—Al₂O₃-based glass frit with 0.1 wt %˜5 wt % Al₂O₃, preferably 0.1 wt %˜3 wt % Al₂O₃.

In one embodiment, G4 glass frit further comprises WO₃ as a SiO₂—TeO₂—PbO—WO₃-based glass frit with 0.1 wt %˜10 wt % WO₃, preferably 1 wt %˜5 wt % WO₃.

In one embodiment, G5 glass frit comprises 30 wt %˜60 wt % TeO₂, preferably 40 wt %˜50 wt % TeO₂.

In one embodiment, G5 glass frit comprises 10 wt %˜40 wt % PbO, preferably 20 wt %˜30 wt % PbO.

In one embodiment, G5 glass frit comprises 10 wt %˜40 wt % Bi₂O₃, preferably 20 wt %˜30 wt % Bi₂O₃.

In one embodiment, G5 glass frit comprises 0.1 wt %˜10 wt % SeO₂, preferably 1 wt %˜5 wt % SeO₂.

In one embodiment, G5 glass frit further comprises Li₂O as a TeO₂—PbO—Bi₂O₃—SeO₂—Li₂O-based glass frit with 0.1 wt %˜10 wt % Li₂O, preferably 1 wt %˜5 wt % Li₂O.

In one embodiment, G5 glass frit further comprises ZnO as a TeO₂—PbO—Bi₂O₃—SeO₂—ZnO-based glass frit with 0.1 wt %˜20 wt % ZnO, preferably 5 wt %˜15 wt % ZnO.

In one embodiment, G5 glass frit further comprises WO₃ as a TeO₂—PbO—Bi₂O₃—SeO₂—WO₃-based glass frit with 0.1 wt %˜10 wt % WO₃, preferably 1 wt %˜5 wt % WO₃.

In one embodiment, G5 glass frit further comprises B₂O₃ as a TeO₂—PbO—Bi₂O₃—SeO₂—B₂O₃-based glass frit with 0.1 wt %˜5 wt % B₂O₃, preferably 0.1 wt %˜3 wt % B₂O₃.

In one embodiment, G5 glass frit further comprises Al₂O₃ as a TeO₂—PbO—Bi₂O₃—SeO₂—Al₂O₃-based glass frit with 0.1 wt %˜5 wt % Al₂O₃, preferably 0.1 wt %˜3 wt % Al₂O₃.

In one embodiment, G6 glass frit comprises 30 wt %˜60 wt % Bi₂O₃, preferably 40 wt %˜50 wt % Bi₂O₃.

In one embodiment, G6 glass frit comprises 5 wt %˜35 wt % SiO₂, preferably 15 wt %˜25 wt % SiO₂. In one embodiment, G6 glass frit comprises 5 wt %˜30 wt % WO₃, preferably 10 wt %˜25 wt % WO₃.

In one embodiment, G6 glass frit further comprises TeO₂ as a Bi₂O₃—SiO₂—WO₃—TeO₂-based glass frit with 0.1 wt %˜20 wt % TeO₂, preferably 5 wt %˜15 wt % TeO₂.

In one embodiment, G6 glass frit further comprises ZnO as a Bi₂O₃—SiO₂—WO₃— ZnO-based glass frit with 0.1 wt %˜20 wt % ZnO, preferably 5 wt %˜15 wt % ZnO.

In one embodiment, G6 glass frit further comprises MgO as a Bi₂O₃—SiO₂—WO₃— MgO-based glass frit with 0.1 wt %˜5 wt % MgO, preferably 3 wt %˜5 wt % MgO.

In one embodiment, G6 glass frit further comprises Li₂O as a Bi₂O₃—SiO₂—WO₃— Li₂O-based glass frit with 0.1 wt %˜10 wt % Li₂O, preferably 1 wt %˜5 wt % Li₂O.

In one embodiment, G6 glass frit further comprises Al₂O₃ as a Bi₂O₃—SiO₂—WO₃—Al₂O₃-based glass frit with 0.1 wt %˜5 wt % Al₂O₃, preferably 0.1 wt %˜3 wt % Al₂O₃.

### Preparation of a Front Electrode of the Solar Cell

A conductive paste comprising crystalline Pb—Te—Bi-oxides (C-320 or C-400) was applied onto the front side of a solar cell substrate by screen printing. The surfaces of the solar cell substrate had been previously treated with an antireflective coating (silicon nitride, SiNx) and the back electrode of the solar cell had been previously treated with an aluminum paste. A drying step was carried out by heated at a temperature of about 100° C. to about 250° C. for about 5 to about 30 minutes after screen printing (condition varies with the type of the organic vehicle and the weight of the printed materials).

A fire-through step was carried out for the dried conductive paste containing a glass frit at a set point (peak firing temperature) of about 900° C. to about 950° C. by means of an IR conveyer type furnace. After fire-through, both front side and back side of the solar cell substrate were formed with solid electrodes.

Solar cells with front electrodes formed from the conductive paste comprising an untreated TeO₂—PbO—Bi₂O₃-based glass frit (G1) (Comparative Examples) were prepared in the same manner.

### Solar Cells Performance Test

The resultant solar cell was subjected to measurements of electrical characteristics using a solar performance testing device (Berger, Pulsed Solar Load PSL-SCD) under AM 1.5 G solar light to determine the open circuit voltage (Uoc), unit: V), short-circuit current (Isc, unit: A), series resistance (Rs, unit: Ω), fill factor (FF, unit: %), conversion efficiency (Ncell, unit: %), pulling force (N/mm), etc. A pulling force in the range of 1.5 to 3.5 N/mm (at least 1.5 N/mm) is normally acceptable in the solar cell industry. The test results are shown in Tables 1 to 5 below.

### DEFINITIONS

“C-400-3 hr” means that the crystalline Pb—Te—Bi-oxides are prepared by heat treatment of the PbO—TeO₂—Bi₂O₃-based glass powder at a temperature of 400° C. for 3 hours.

“C-320-0 hr” means that the crystalline Pb—Te—Bi-oxides are prepared by heating the PbO—TeO₂—Bi₂O₃-based glass powder from the room temperature to 320° C., followed by cooling down without constantly heat treatment at 320° C.

“C-320-3 hr” means that the crystalline Pb—Te—Bi-oxides are prepared by heating the PbO—TeO₂—Bi₂O₃-based glass powder at 320° C. for 3 hours.

“C-320-9 hr” means that the crystalline Pb—Te—Bi-oxides are prepared by heating the PbO—TeO₂—Bi₂O₃-based glass powder at 320° C. for 9 hours.

“C-320-24 hr” means that the crystalline Pb—Te—Bi-oxides are prepared by heating the PbO—TeO₂—Bi₂O₃-based glass powder at 320° C. for 24 hours.

“G1-H” means that the crystalline Pb—Te—Bi-oxides are prepared by heating the PbO—TeO₂—Bi₂O₃-based glass powder at 320° C. for 24 hours.

### Test Results

TABLE 1
Electrical Characteristics and Pulling Force of Solar Cells Produced from
Conductive Pastes Containing Untreated Glass or Crystalline Oxides
Powder After Heat Treatment at 400° C. for 3 hours

| | | | | | | | Pulling |
|---|---|---|---|---|---|---|---|
| | Peak firing | | | | | | test, |
| | temperature | | | | | | Avg |
| Charge | (° C.) | Uoc | Isc | Rs | FF | NCell | (N/mm) |
| G1 + G2 | 920 | 0.6238 | 8.308 | 0.00206 | 78.93 | 16.81% | 2.71 |
| (Comparative | | 0.6254 | 8.346 | 0.00236 | 78.93 | 16.93% | |
| Example) | | 0.6247 | 8.346 | 0.00243 | 78.75 | 16.87% | |
| | | 0.6240 | 8.341 | 0.00232 | 78.80 | 16.85% | |
| | | 0.6238 | 8.341 | 0.00239 | 78.57 | 16.80% | |
| | | 0.6239 | 8.325 | 0.00237 | 78.66 | 16.79% | |
| Average | | 0.6243 | 8.335 | 0.00232 | 78.77 | 16.84% | |
| C-400- | 910 | 0.6253 | 8.402 | 0.00245 | 78.38 | 16.92% | 2.57 |
| 3 hr + G2 | | 0.6250 | 8.416 | 0.00251 | 78.00 | 16.86% | |
| (Example, the | | 0.6257 | 8.407 | 0.00250 | 78.65 | 17.00% | |
| present | | 0.6252 | 8.405 | 0.00247 | 78.67 | 16.99% | |
| invention) | | 0.6249 | 8.402 | 0.00237 | 78.50 | 16.94% | |
| | | 0.6247 | 8.403 | 0.00233 | 78.58 | 16.95% | |
| Average | | 0.6251 | 8.406 | 0.00244 | 78.46 | 16.94% | |
| C-400- | 920 | 0.6240 | 8.379 | 0.00238 | 78.34 | 16.83% | 2.47 |
| 3 hr + G2 | | 0.6242 | 8.388 | 0.00240 | 78.42 | 16.87% | |
| (Example, the | | 0.6242 | 8.381 | 0.00240 | 78.65 | 16.91% | |
| present | | 0.6236 | 8.372 | 0.00235 | 78.67 | 16.88% | |
| invention) | | 0.6231 | 8.373 | 0.00229 | 78.68 | 16.87% | |
| | | 0.6230 | 8.365 | 0.00228 | 78.56 | 16.82% | |
| Average | | 0.6237 | 8.376 | 0.00235 | 78.55 | 16.86% | |

In Table 1, 2 g of G1 or C-400-3 hr and 0.25 g of G2 were used. From the performance test data in Table 1, it can be seen that the crystalline Pb—Te—Bi-oxide powder imparts the resultant solar cell with better photovoltaic conversion efficiency than the untreated glass and a comparable pulling force. Moreover, firing-through carried out at a set point (peak firing temperature) of 910° C. leads the resultant solar cell to have a better photovoltaic conversion efficiency than the one obtained by firing-through at a temperature of 920° C.

TABLE 2
Electrical Characteristics of Solar Cells Produced from
Conductive Pastes Containing Crystalline Oxides Powder
Treated at 320° C. for 0-9 hours and fire-through
at the set point (peak firing temperature) of 910° C.

| Charge | Uoc | Isc | Rs | FF | NCell |
|---|---|---|---|---|---|
| C-320- | 0.6243 | 8.424 | 0.00230 | 79.10 | 17.09% |
| 0 hr + G2 | 0.6239 | 8.444 | 0.00227 | 78.95 | 17.09% |
| (Comparative | 0.6245 | 8.453 | 0.00231 | 78.99 | 17.13% |
| Example) | 0.6236 | 8.454 | 0.00223 | 78.73 | 17.06% |
| | 0.6246 | 8.456 | 0.00230 | 78.80 | 17.10% |
| Average | 0.6242 | 8.446 | 0.00228 | 78.91 | 17.09% |
| C-320- | 0.6245 | 8.457 | 0.00226 | 79.00 | 17.14% |
| 3 hr + G2 | 0.6252 | 8.464 | 0.00231 | 78.98 | 17.17% |
| (Example, | 0.6246 | 8.457 | 0.00231 | 78.98 | 17.14% |
| the present | 0.6253 | 8.473 | 0.00228 | 78.84 | 17.16% |
| invention) | 0.6255 | 8.469 | 0.00239 | 78.92 | 17.18% |
| Average | 0.6250 | 8.464 | 0.00231 | 78.94 | 17.16% |
| C-320- | 0.6253 | 8.472 | 0.00221 | 78.99 | 17.20% |
| 9 hr + G2 | 0.6257 | 8.463 | 0.00222 | 79.06 | 17.20% |
| (Example, | 0.6254 | 8.475 | 0.00230 | 78.88 | 17.18% |
| the present | 0.6261 | 8.486 | 0.00220 | 78.98 | 17.24% |
| invention | 0.6266 | 8.495 | 0.00220 | 78.88 | 17.25% |
| Average | 0.6258 | 8.478 | 0.00222 | 78.96 | 17.21% |

TABLE 3
Electrical Characteristics of Solar Cells Produced from
Conductive Pastes Containing Crystalline Oxides Powder
Treated at 320° C. for 0-9 hours and fire-through
at the set point (peak firing temperature) of 920° C.

| Charge | Uoc | Isc | Rs | FF | NCell |
|---|---|---|---|---|---|
| G1 + G2 | 0.6254 | 8.403 | 0.00222 | 79.00 | 17.06% |
| (Comparative | 0.6250 | 8.420 | 0.00221 | 79.09 | 17.10% |
| Example) | 0.6249 | 8.420 | 0.00219 | 79.20 | 17.13% |
| | 0.6243 | 8.413 | 0.00223 | 78.88 | 17.02% |
| | 0.6256 | 8.416 | 0.00215 | 79.13 | 17.12% |
| Average | 0.6250 | 8.414 | 0.00220 | 79.06 | 17.09% |
| C-320- | 0.6233 | 8.412 | 0.00217 | 79.15 | 17.05% |
| 0 hr + G2 | 0.6234 | 8.419 | 0.00222 | 79.02 | 17.04% |
| (Comparative | 0.6244 | 8.420 | 0.00243 | 78.86 | 17.04% |
| Example) | 0.6249 | 8.416 | 0.00220 | 79.17 | 17.11% |
| | 0.6249 | 8.421 | 0.00225 | 79.12 | 17.11% |
| Average | 0.6242 | 8.418 | 0.00225 | 79.06 | 17.07% |
| C-320- | 0.6249 | 8.436 | 0.00228 | 79.01 | 17.11% |
| 3 hr + G2 | 0.6242 | 8.434 | 0.00229 | 79.02 | 17.09% |
| (Example, | 0.6242 | 8.432 | 0.00212 | 79.22 | 17.13% |
| the present | 0.6253 | 8.436 | 0.00220 | 79.05 | 17.14% |
| invention) | 0.6246 | 8.429 | 0.00224 | 78.99 | 17.09% |
| Average | 0.6246 | 8.433 | 0.00223 | 79.06 | 17.11% |
| C-320- | 0.6251 | 8.454 | 0.00219 | 79.13 | 17.18% |
| 9 hr + G2 | 0.6252 | 8.459 | 0.00227 | 78.94 | 17.15% |
| (Example, | 0.6257 | 8.462 | 0.00221 | 79.24 | 17.24% |
| the present | 0.6256 | 8.458 | 0.00229 | 79.06 | 17.19% |
| invention) | 0.6264 | 8.463 | 0.00228 | 79.00 | 17.21% |
| Average | 0.6256 | 8.459 | 0.00225 | 79.07 | 17.20% |

In Tables 2 and 3, 2 g of C-320-0 hr, C-320-3 hr or C320-9 hr and 0.25 g of G2 were used. From the performance test data in Tables 2 and 3, it can be seen that the longer the heat treatment is performed, the better the photovoltaic conversion efficiency of the solar cell would be produced.

TABLE 4
Electrical Characteristics and Pulling Force of Solar Cells Produced from
Conductive Pastes Containing Crystalline Oxides Powder Treated at 320° C. for 9
or 24 hours and fire-through at the set point (peak firing temperature) of 910° C.

| | | | | | | | | | Pulling |
|---|---|---|---|---|---|---|---|---|---|
| Component | | Component | | | | | | NCell | test |
| 1 | | 2 | | Uoc | Isc | Rs | FF | (%) | (N/mm) |
| G1 | 2 g | G2 | 0.25 g | 0.6258 | 8.450 | 0.00241 | 78.90 | 17.15 | 2.75 |
| (Comparative | | | | | | | | | |
| Example) | | | | | | | | | |
| C-320-9 hr | 2 g | G2 | 0.25 g | 0.6260 | 8.503 | 0.00249 | 78.81 | 17.24 | 2.33 |
| (Example, | 1.75 g | | 0.25 g | 0.6265 | 8.497 | 0.00251 | 78.87 | 17.25 | 2.65 |
| the present | 1.5 g | | 0.25 g | 0.6259 | 8.484 | 0.00245 | 78.81 | 17.20 | 2.64 |
| invention) | 1.75 g | | 0.5 g | 0.6266 | 8.506 | 0.00252 | 78.78 | 17.25 | 3.08 |
| | 1.5 g | | 0.5 g | 0.6260 | 8.506 | 0.00254 | 78.85 | 17.25 | 3.07 |
| G1 | 2 g | G2 | 0.25g | 0.6270 | 8.449 | 0.00248 | 79.11 | 17.22 | N/D |
| (Comparative | | | | | | | | | |
| Example) | | | | | | | | | |
| C-320-24 hr | 2 g | G2 | 0.25 g | 0.6281 | 8.469 | 0.00253 | 79.02 | 17.27 | N/D |
| (Example, | 1.75 g | | 0.25 g | 0.6282 | 8.468 | 0.00257 | 78.99 | 17.26 | N/D |
| the present | 1.5 g | | 0.25 g | 0.6281 | 8.468 | 0.00261 | 78.84 | 17.23 | N/D |
| invention) | 1.75 g | | 0.5 g | 0.6280 | 8.483 | 0.00262 | 78.91 | 17.28 | N/D |
| | 1.5 g | | 0.5 g | 0.6282 | 8.477 | 0.00266 | 78.92 | 17.27 | N/D |
| G1 | 2 g | G2 | 0.25 g | 0.6251 | 8.440 | 0.00272 | 78.18 | 16.95 | 2.67 |
| (Comparative | | | | | | | | | |
| Example) | | | | | | | | | |
| C-320-24 hr | 2 g | G2 | 0.25 g | 0.6258 | 8.467 | 0.00273 | 78.14 | 17.01 | 2.36 |
| (Example, | 1.75 g | | 0.5 g | 0.6259 | 8.471 | 0.00282 | 77.97 | 16.99 | 2.89 |
| the present | 1.85 g | | 0.75 g | 0.6264 | 8.472 | 0.00284 | 78.04 | 17.02 | 3.17 |
| invention) | | | | | | | | | |

Table 4 shows the effect of weight ratios of G1, C-320-9 hr or C-320-24 hr to G2 in the electrical characteristics and pulling force of solar cells. It appears that the increased amount of G2 would enhance the pulling force of the resultant solar cells and the pulling force of the solar cell may be increased to a maximum of 3.17 N/mm.

TABLE 5
Electrical Characteristics and Pulling Force of Solar Cells Produced from
Conductive Pastes Containing Crystalline Oxides Powder Alone or in Combination
with G2

| | | | | Peak firing | | | | | |
|---|---|---|---|---|---|---|---|---|---|
| Component | | | | temperature | | | | | NCell |
| 1 | | Component 2 | | (° C.) | Uoc | Isc | Rs | FF | (%) |
| G1 | 2 g | G2 | 0.25 g | 910 | 0.6268 | 8.277 | 0.00285 | 78.09 | 17.02 |
| (Comparative | 2 g | | 0 g | | 0.6268 | 8.281 | 0.00292 | 78.04 | 17.02 |
| Example) | | | | | | | | | |
| C-320-24 hr | 2 g | G2 | 0.25 g | | 0.6270 | 8.294 | 0.00288 | 78.10 | 17.06 |
| (Example, the | 2 g | | 0. g | | 0.6269 | 8.293 | 0.00289 | 78.13 | 17.07 |
| present | | | | | | | | | |
| invention) | | | | | | | | | |
| G1 | 2 g | G2 | 0.25 g | 920 | 0.6265 | 8.280 | 0.00289 | 77.92 | 16.98 |
| (Comparative | 2 g | | 0 g | | 0.6265 | 8.281 | 0.00287 | 78.01 | 17.00 |
| Example) | | | | | | | | | |
| C-320-24 hr | 2 g | G2 | 0.25 g | | 0.6266 | 8.300 | 0.00292 | 78.01 | 17.05 |
| (Example, the | 2 g | | 0. g | | 0.6266 | 8.300 | 0.00287 | 78.05 | 17.05 |
| present | | | | | | | | | |
| invention) | | | | | | | | | |

The data in Table 5 refers to average values of multiple testing. Table 5 shows that in the absence of G2, the crystalline oxides of the present invention still would lead the resultant solar cell to have superior photovoltaic conversion efficiency to the one using untreated glass.

In summary, the data in Tables 1 to 5 demonstrates the crystalline oxides of the present invention would result in an increased photovoltaic conversion efficiency and comparable pulling force, as compared with the conventional glass frit.

TABLE 6
Electrical Characteristics of Solar Cells Produced from Conductive Pastes
Containing Untreated Glass or Crystalline Oxides Powder After Heat Treatment at
320° C. for 24 hours in Combination with TeO₂—Bi₂O₃-based Glass Frit (G3)

| | | Peak firing | | | | | |
|---|---|---|---|---|---|---|---|
| | | temperature | Uoc | Isc | Rs | | NCell |
| Charge | | (° C.) | (V) | (A) | (Ω) | FF | (%) |
| G1 | G2 | 920 | 0.6286 | 8.790 | 0.00178 | 79.27 | 18.00 |
| 2 g | 0.25 g | | 0.6273 | 8.766 | 0.00170 | 79.14 | 17.88 |
| G1-H | G3 | 910 | 0.6287 | 8.822 | 0.00188 | 79.09 | 18.02 |
| 2 g | 0.25 g | | 0.6282 | 8.796 | 0.00189 | 79.43 | 18.03 |
| G1-H | G3 | 910 | 0.6289 | 8.796 | 0.00184 | 79.23 | 18.01 |
| 1.75 g | 0.25 g | | 0.6288 | 8.802 | 0.00190 | 79.20 | 18.01 |
| G1-H | G3 | 910 | 0.6292 | 8.773 | 0.00177 | 79.54 | 18.04 |
| 1.5 g | 0.25 g | | 0.6300 | 8.806 | 0.00186 | 79.26 | 18.07 |
| G1-H | G3 | 910 | 0.6286 | 8.782 | 0.00185 | 79.39 | 18.01 |
| 1.75 g | 0.5 g | | 0.6288 | 8.802 | 0.00182 | 79.29 | 18.03 |
| G1-H | G3 | 910 | 0.6293 | 8.794 | 0.00178 | 79.32 | 18.04 |
| 1.5 g | 0.5 g | | 0.6290 | 8.807 | 0.00188 | 79.36 | 18.06 |

TABLE 7
Electrical Characteristics of Solar Cells Produced from Conductive Pastes
Containing Untreated Glass or Crystalline Oxides Powder After Heat Treatment at
320° C. for 24 hours in Combination with SiO₂—TeO₂—PbO-based Glass Frit (G4)

| | | Peak firing | | | | | |
|---|---|---|---|---|---|---|---|
| | | temperature | Uoc | Isc | Rs | | NCell |
| Charge | | (° C.) | (V) | (A) | (Ω) | FF | (%) |
| G1 | G2 | 920 | 0.6286 | 8.790 | 0.00178 | 79.27 | 18.00 |
| 2 g | 0.25 g | | 0.6273 | 8.766 | 0.00170 | 79.14 | 17.88 |
| G1-H | G4 | 910 | 0.6285 | 8.798 | 0.00191 | 79.25 | 18.00 |
| 2 g | 0.25 g | | 0.6284 | 8.795 | 0.00181 | 79.19 | 17.98 |
| G1-H | G4 | 910 | 0.6293 | 8.800 | 0.00187 | 79.23 | 18.03 |
| 1.75 g | 0.25 g | | 0.6288 | 8.788 | 0.00193 | 79.25 | 17.99 |
| G1-H | G4 | 910 | 0.6292 | 8.798 | 0.00190 | 79.22 | 18.02 |
| 1.5 g | 0.25 g | | 0.6295 | 8.777 | 0.00189 | 79.33 | 18.01 |
| G1-H | G4 | 910 | 0.6288 | 8.798 | 0.00185 | 79.36 | 18.04 |
| 1.75 g | 0.5 g | | 0.6285 | 8.792 | 0.00184 | 79.30 | 18.00 |
| G1-H | G4 | 910 | 0.6291 | 8.795 | 0.00185 | 79.20 | 18.01 |
| 1.5 g | 0.5 g | | 0.6294 | 8.797 | 0.00189 | 79.09 | 17.99 |

TABLE 8
Electrical Characteristics of Solar Cells Produced from Conductive Pastes
Containing Untreated Glass or Crystalline Oxides Powder After Heat Treatment at
320° C. for 24 hours in Combination with TeO₂—PbO—Bi₂O₃—SeO₂-based Glass Frit (G5)

| | | Peak firing | | | | | |
|---|---|---|---|---|---|---|---|
| | | temperature | Uoc | Isc | Rs | | NCell |
| Charge | | (° C.) | (V) | (A) | (Ω) | FF | (%) |
| G1 | G2 | 920 | 0.6267 | 8.746 | 0.00178 | 79.40 | 17.88 |
| 2 g | 0.25 g | | 0.6265 | 8.761 | 0.00185 | 79.31 | 17.89 |
| G1-H | G5 | 910 | 0.6283 | 8.784 | 0.00207 | 78.97 | 17.91 |
| 2 g | 0.25 g | | 0.6283 | 8.781 | 0.00198 | 79.05 | 17.92 |
| G1-H | G5 | 910 | 0.6288 | 8.773 | 0.00201 | 79.20 | 17.95 |
| 1.75 g | 0.25 g | | 0.6291 | 8.783 | 0.00196 | 79.23 | 17.99 |
| G1-H | G5 | 910 | 0.6292 | 8.787 | 0.00204 | 79.13 | 17.98 |
| 1.5 g | 0.25 g | | 0.6296 | 8.787 | 0.00189 | 79.28 | 18.02 |
| G1-H | G5 | 910 | 0.6283 | 8.788 | 0.00198 | 79.25 | 17.98 |
| 1.75 g | 0.5 g | | 0.6289 | 8.791 | 0.00205 | 79.22 | 18.00 |
| G1-H | G5 | 910 | 0.6289 | 8.775 | 0.00191 | 79.30 | 17.98 |
| 1.5 g | 0.5 g | | 0.6286 | 8.777 | 0.00190 | 79.37 | 17.99 |

TABLE 9
Electrical Characteristics of Solar Cells Produced from Conductive Pastes
Containing Untreated Glass or Crystalline Oxides Powder After Heat Treatment at
320° C. for 24 hours in Combination with Bi₂O₃—SiO₂—WO₃-based Glass Frit (G6)

| | | Peak firing | | | | | |
|---|---|---|---|---|---|---|---|
| | | temperature | Uoc | Isc | Rs | | NCell |
| Charge | | (° C.) | (V) | (A) | (Ω) | FF | (%) |
| G1 | G2 | 920 | 0.6267 | 8.746 | 0.00178 | 79.40 | 17.88 |
| 2 g | 0.25 g | | 0.6265 | 8.761 | 0.00185 | 79.31 | 17.89 |
| G1-H | G6 | 910 | 0.6281 | 8.773 | 0.00184 | 78.90 | 17.86 |
| 2 g | 0.25 g | | 0.6284 | 8.770 | 0.00186 | 79.30 | 17.96 |
| G1-H | G6 | 910 | 0.6289 | 8.775 | 0.00187 | 79.01 | 17.92 |
| 1.75 g | 0.25 g | | 0.6297 | 8.785 | 0.00187 | 79.15 | 17.99 |
| G1-H | G6 | 910 | 0.6295 | 8.776 | 0.00192 | 78.98 | 17.93 |
| 1.5 g | 0.25 g | | 0.6292 | 8.780 | 0.00191 | 79.17 | 17.97 |
| G1-H | G6 | 910 | 0.6291 | 8.776 | 0.00200 | 78.99 | 17.92 |
| 1.75 g | 0.5 g | | 0.6281 | 8.766 | 0.00190 | 79.20 | 17.92 |
| G1-H | G6 | 910 | 0.6293 | 8.770 | 0.00201 | 79.22 | 17.95 |
| 1.5 g | 0.5 g | | 0.6288 | 8.768 | 0.00189 | 79.22 | 17.96 |

“G1+G2” in Tables 6-9 represents the glass frit commonly used in the art. Tables 6-9 demonstrate that conductive pastes comprising the crystalline Pb—Te—Bi-oxide of the present invention (G1-H) and the TeO₂—Bi₂O₃-based glass frit (G3), the TeO₂—PbO—Bi₂O₃—SeO₂-based glass frit (G5) or the Bi₂O₃—SiO₂—WO₃ (G6) would lead the resultant solar cells to have comparable or even superior photovoltaic conversion efficiency to the ones using conventional glass grits.

The above preferred examples are only used to illustrate the technical features of the present invention and the technical effects thereof. The technical content of said examples can still be practiced by substantially equivalent combination, modifications, replacements and/or conversions. Accordingly, the protection scope of the present invention is based on the scope of the inventions defined by the appended claims.

1. A crystalline Pb—Te—Bi-oxide represented by the formula BiₐPb_{b}Te_{c}O_{d}, wherein the stoichiometric a=0-32, b=0-6, c=1-4 and d=0.6-50.

2. The crystalline Pb—Te—Bi-oxide according to claim 1, wherein a=0, b=1-3, c=1-3 and d=3-8.

3. The crystalline Pb—Te—Bi-oxide according to claim 1, wherein a=1-4, b=0, c=1-3 and d=0.6-11.

4. The crystalline Pb—Te—Bi-oxide according to claim 1, wherein a=6, b=1, c=1 and d=12.

5. The crystalline Pb—Te—Bi-oxide according to claim 1, wherein the crystalline Pb—Te—Bi-oxide is in at least one forms of cubic (C), tetragonal (T), monoclinic (M) or orthorhombic (O) crystalline structure

6. The crystalline Pb—Te—Bi-oxide according to claim 5, wherein the crystalline Pb—Te—Bi-oxide comprises one or more selected from of Pb₂TeO₅ (M), Pb₂Te₃O₈ (O), PbTeO₃ (T), PbTeO₃ (M), Pb₃TeO₆ (M), Pb₅TeO₇, Pb₄Te_{1.5}O₇ (O), Pb₃TeO₅, Pb₂TeO₄ (M), Pb₂Te₃O₈ (O), Pb₂Te₃O₇ (C), Pb₃TeO₅ (C), PbTeO₃ (C), PbTeO₄ (T), PbTe₃O₇ (C), PbTeO₃ (O), PbBi₆TeO₁₂, (Bi₂Te₄O₁₁)_{0.6} (C), Bi₂Te₂O₇ (O), Bi₂Te₂O₈ (M), Bi₂Te₄O₁₁ (M), Bi₂TeO₅ (O), Bi₂TeO₆ (O), Bi₂Te₄O₁₁ (C), Bi₆Te₂O₁₃ (O), BiTe₃O_{7.5} (C), Bi₂Te₂O₇, Bi₆Te₂O₁₅ (O), Bi₃₂TeO₅₀ (T), Bi₄TeO₈ (C), Bi₁₆Te₅O₃₄ (T).

7. A process for preparing crystalline Pb—Te—Bi-oxides according to claim 1 comprising the steps of: (i) providing a PbO—TeO₂—Bi₂O₃-based glass and (ii) treating said glass at a crystallization temperature for about 3 to about 24 hours.

8. The process according to claim 7, wherein the PbO—TeO₂—Bi₂O₃-based glass is in the form of powder.

9. The process according to claim 7, wherein the crystallization temperature is about 320° C. to about 400° C.

10. A conductive paste comprising:
(a) about 85% to about 99.5% by weight of a conductive metal or the derivative thereof, based on the weight of solids;
(b) about 0.5% to about 15% by weight of a crystalline Pb—Te—Bi-oxide according to claim 1; and
(c) an organic vehicle;
wherein the weight of solids is the total weight of (a) and (b).

11. The conductive paste according to claim 10, wherein the conductive metal or the derivative substantially comprise silver as main component.

12. The conductive paste according to claim 10, which further comprises (d) a Bi₂O₃—SiO₂-based glass frit; and the weight ratio of the crystalline Pb—Te—Bi-oxides to the Bi₂O₃—SiO₂-based glass in the conductive paste is about 2.5:1 to about 8:1.

13. The conductive paste according to claim 10, wherein the crystalline Pb—Te—Bi-oxide further comprises one or more elements selected from the group consisting of silicon (Si), boron (B), phosphorus (P), barium (Ba), sodium (Na), magnesium (Mg), zinc (Zn), calcium (Ca), strontium (Sr), tungsten (W), aluminum (Al), lithium (Li), potassium (K), zirconium (Zr), vanadium (V), selenium (Se), iron (Fe), indium (In), molybdenum (Mo), manganese (Mn), tin (Sn), nickel (Ni), antimony (Sb), silver (Ag), erbium (Er), germanium (Ge), titanium (Ti), gallium (Ga), cerium (Ce), niobium (Nb), samarium (Sm) and lanthanum (La) or the oxide thereof.

14. The conductive paste according to claim 12, wherein the Bi₂O₃—SiO₂-based glass frit further comprises one or more elements selected from the group consisting of silicon (Si), boron (B), phosphorus (P), barium (Ba), sodium (Na), magnesium (Mg), zinc (Zn), calcium (Ca), tellurium (Te), strontium (Sr), tungsten (W), aluminum (Al), lithium (Li), potassium (K), zirconium (Zr), lead (Pb), vanadium (V), selenium (Se), iron (Fe), indium (In), manganese (Mn), tin (Sn), nickel (Ni), antimony (Sb), silver (Ag), molybdenum (Mo), erbium (Er), germanium (Ge), titanium (Ti), gallium (Ga), cerium (Ce), niobium (Nb), samarium (Sm) and lanthanum (La) or the oxide thereof in an amount of about 0.1 mole % to about 30 mole % of the Bi₂O₃—SiO₂-based glass frit.

15. The conductive paste according to claim 10, which further comprises (e) a TeO₂—Bi₂O₃-based glass frit; and the weight ratio of the crystalline Pb—Te—Bi-oxides to the TeO₂—Bi₂O₃-based glass in the conductive paste is about 2.5:1 to about 8:1.

16. The conductive paste according to claim 10, which further comprises (f) a SiO₂—TeO₂—PbO-based glass frit; and the weight ratio of the crystalline Pb—Te—Bi-oxides to the SiO₂—TeO₂—PbO-based glass in the conductive paste is about 2.5:1 to about 8:1.

17. The conductive paste according to claim 10, which further comprises (g) a TeO₂—PbO—Bi₂O₃—SeO₂-based glass frit; and the weight ratio of the crystalline Pb—Te—Bi-oxides to the TeO₂—PbO—Bi₂O₃—SeO₂-based glass in the conductive paste is about 2.5:1 to about 8:1.

18. The conductive paste according to claim 10, which further comprises (h) a Bi₂O₃—SiO₂—WO₃-based glass frit; and the weight ratio of the crystalline Pb—Te—Bi-oxides to the Bi₂O₃—SiO₂—WO₃-based glass in the conductive paste is about 2.5:1 to about 8:1.

19. An article comprising a semiconductor substrate and a conductive paste according to claim 10 applied onto the semiconductor substrate.

20. The article according to claim 19, which further comprises one or more antireflective coatings applied onto the semiconductor substrate; and
wherein the conductive paste contacts the antireflective coating(s) and has electrical contact with the semiconductor substrate.

21. The article according to claim 19, which is a semiconductor device.

22. The article according to claim 21, wherein the semiconductor device is a solar cell.
